(19) United States
(12) Patent Application Publication
(10) Pub. No.: US 2008/0211593 A1
(43) Pub. Date: Sep. 4, 2008

(54) Oscillation circuit

(76) Inventors: Yutaka Sato, Chiba-shi (JP); Kotaro Watanabe, Chiba-shi (JP)

Correspondence Address: BRUCE L. ADAMS, ESQ;ADAMS & WILKS, SUITE 1231, 17 BATTERY PLACE, NEW YORK, NY, 10004, US

(21) Appl. No.: 12/070,210

(22) Filed: Feb. 15, 2008

(30) Foreign Application Priority Data
Feb. 17, 2007 (JP) 2007-037217

(51) Int. Cl. H03B 5/32

(52) U.S. Cl. 331/160; 331/158

(57) ABSTRACT

Provided is an oscillation circuit capable of obtaining a plurality of oscillation frequencies using a single oscillation resonator. The oscillation circuit includes the oscillation resonator, an oscillation inverter, a dumping resister connected between an output of the oscillation inverter and an output terminal, a feedback resistor connected with input and output of the oscillation inverter, and a feedback resistor switch for varying a feedback resistance value or an oscillation inverter switch for varying a mutual conductance value of the oscillation inverter. When the feedback resistance value or the mutual conductance value of the oscillation inverter is varied by the feedback resistor switch or the oscillation inverter switch, a frequency band of the oscillation circuit is adjusted to select a harmonic component of the oscillation resonator. Therefore, an oscillation frequency can be switched, so it is possible to obtain a plurality of oscillation frequencies using a single oscillation resonator.

### BACKGROUND OF THE INVENTION

1. Field of the Invention

The present invention relates to an oscillation circuit, and more particularly, to an oscillation circuit capable of obtaining a plurality of oscillation frequencies using a single quartz resonator.

2. Description of the Related Art

Up to now, a frequency switching oscillator using a quartz resonator requires two oscillation circuits oscillating at different frequencies, and employs a method in which any one of the two oscillation circuits is chosen by switching a switch to obtain different oscillation frequencies.

For example, two oscillation circuits are incorporated into a clock. One of two quartz resonators is used for time measurement. The other of the quartz resonators is used for the control of the oscillation circuits. Further, for example, there is a case in which in a control board, each of two frequencies obtained from two quartz resonators is used for the control thereof.

As the oscillator described above, there has been known one described in, for example, JP 2004-140817 A, JP 2005-167572 A, and JP 2005-086378 A.

However, the oscillators described in JP 2004-140817 A, JP 2005-167572 A, and JP 2005-086378 A each require two quartz resonators and corresponding oscillation circuits for frequency switching, so there is a problem in that the resonator is large in its area and thus a cost thereof increases.

When a function of the clock for measuring a time using the quartz resonator is to be tested, a frequency of the quartz resonator for time measurement, for example, 32.768 kHz is used for function test. The frequency of the quartz resonator for time measurement is relatively low, so there is a problem in that a period of time required for the function test of the clock is prolonged.

The function test used herein means a test for checking whether or not a frequency divider circuit performs a normal frequency dividing operation, though a frequency of 32.768 kHz from the oscillation circuit using the quartz resonator is divided by the frequency divider circuit to generate 1 Hz, for instance.

In order to execute the function test, a frequency may be inputted from an outside to the clock without using the frequency from the oscillation circuit. In this case, the period of time required for the function test of the clock is shortened. However, there is a problem in that the oscillation circuit itself cannot be tested.

### SUMMARY OF THE INVENTION

The present invention has been made in view of the circumstances described above. An object of the present invention is to provide an oscillation circuit capable of obtaining a plurality of oscillation frequencies using a single quartz resonator (oscillation resonator).

The present invention has been made to solve the above-mentioned problems. An oscillation circuit according to the present invention has the following structure.

That is, the oscillation circuit includes: an oscillation resonator; an oscillation inverter which is connected in parallel with the oscillation resonator and includes an output terminal; a dumping resistor connected with the output terminal of the oscillation inverter; and a feedback resistor which is connected in parallel with the oscillation inverter and has a variable resistance value. The oscillation circuit further includes an oscillation inverter switch for adjusting a current drive capacity of the oscillation inverter.

Further, the oscillation circuit includes: an oscillation resonator; an oscillation inverter which is connected in parallel with the oscillation resonator and includes an output terminal; a dumping resistor connected with the output terminal of the oscillation inverter; and a feedback resistor which is connected in parallel with the oscillation inverter; and an oscillation inverter switch for adjusting a current drive capacity of the oscillation inverter. Further, the feedback resistor has a variable resistance value.

Further, the feedback resistor includes: a first feedback resistor; a second feedback resistor; and a feedback resistor switch connected in parallel with the second feedback resistor.

Further, the second feedback resistor includes a plurality of the feedback resistors and the feedback resistor switch includes a plurality of the feedback resistor switches.

Further, the oscillation inverter includes a plurality of transistors and the number of transistors to be operated is changed based on an input of the oscillation inverter switch.

Further, the oscillation inverter includes: a plurality of oscillation inverter circuits having different current drive capabilities; and an oscillation inverter circuit selection switch for selecting an oscillation inverter circuit from the plurality of oscillation inverter circuits based on an input of the oscillation inverter switch.

Further, the oscillation inverter includes: a variable voltage supply for generating a variable voltage based on an input of the oscillation inverter switch; and an oscillation inverter circuit driven at the variable voltage inputted from the variable voltage supply.

According to the present invention, the oscillation circuit includes the oscillation resonator, the oscillation inverter, the dumping resister connected between the output of the oscillation inverter and the output terminal, the feedback resistor connected with the input and output of the oscillation inverter, and the feedback resistor switch for varying the feedback resistance value or the oscillation inverter switch for varying the mutual conductance value of the oscillation inverter. Therefore, when the feedback resistance value or the mutual conductance value of the oscillation inverter is varied by the feedback resistor switch or the oscillation inverter switch, a frequency band of the oscillation circuit is adjusted to select a harmonic component of the oscillation resonator. Thus, an oscillation frequency can be switched, so it is possible to obtain a plurality of oscillation frequencies using a single oscillation resonator.

According to the present invention, the quartz oscillation circuit obtains the plurality of oscillation frequencies using the single oscillation resonator, so there is an effect that an oscillation circuit in which the number of elements is small and a chip area its narrow can be provided.

According to the present invention, the quartz oscillation circuit obtains the plurality of oscillation frequencies using the single oscillation resonator, so there is an effect that the oscillation circuit in which the number of elements is small and a chip area is narrow can be provided to reduce a manufacturing cost of the quartz oscillation circuit.

According to the present invention, the quartz oscillation circuit can obtain the plurality of oscillation frequencies using the single oscillation resonator. Therefore, when the oscillation resonator is operated for a function test at a high frequency, there is an effect that a period of time required for the function test can be shortened.

According to the present invention, the quartz oscillation circuit can obtain the plurality of oscillation frequencies using the single oscillation resonator. Therefore, when the oscillation resonator is operated for a function test at a high frequency, there is an effect that not only a period of time required for the function test can be shortened but also the operation of the oscillation circuit itself can be checked.

### BRIEF DESCRIPTION OF THE DRAWINGS

In the accompanying drawings:

FIG. 1 is a circuit diagram showing an oscillation circuit according to a first embodiment of the present invention;

FIG. 2 is a frequency characteristic diagram showing frequency characteristics of the oscillation circuit of FIG. 1;

FIG. 3 is a circuit diagram showing an oscillation circuit according to a second embodiment of the present invention;

FIG. 4A is a diagram showing an oscillation inverter according to a third embodiment of the present invention, FIG. 4B is a circuit diagram showing an oscillation circuit according to the third embodiment of the present invention, and FIG. 4C shows a table summarizing an operation of the oscillation inverter according to the third embodiment of the present invention; and

FIG. 5A is a diagram showing an oscillation inverter according to a fourth embodiment of the present invention and FIG. 5B is a circuit diagram showing an oscillation circuit according to the fourth embodiment of the present invention.

### DETAILED DESCRIPTION OF THE PREFERRED EMBODIMENTS

### First Embodiment

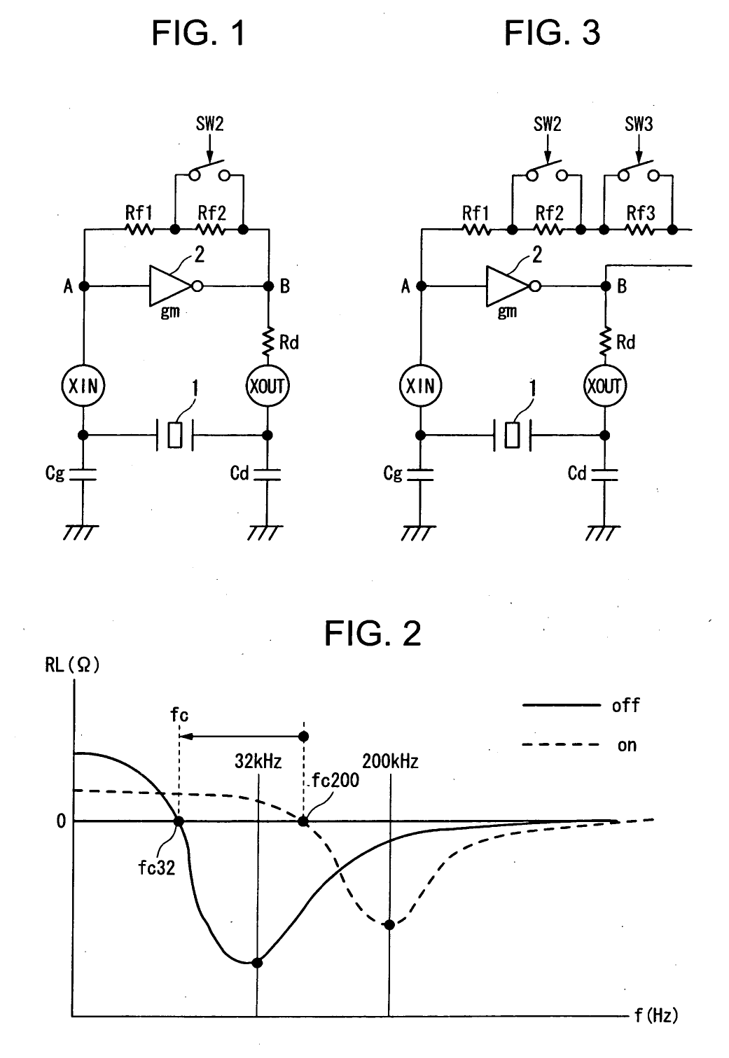

Hereinafter, a first embodiment of the present invention will be described with reference to the drawings. FIG. 1 is a schematic block diagram showing a structure of an oscillation circuit according to the first embodiment of the present invention.

The oscillation circuit includes an oscillation inverter 2, feedback resistors Rf1 and Rf2, a dumping resistor Rd, and a switch SW2 (feedback resistor switch).

The oscillation inverter 2 is, for example, a CMOS oscillation inverter composed of a P-channel MOS transistor and an N-channel MOS transistor. Both ends (input and output terminals) of the oscillation inverter 2 are connected with the feedback resistors Rf1 and Rf2 connected in series. The output terminal of the oscillation inverter 2 is connected with an end of the dumping resistor Rd.

The switch SW2 is a switch for determining whether or not the feedback resistor Rf2 is enabled (short-circuited) in the case where the feedback resistors Rf1 and Rf2 connected in series are connected with both the ends of the oscillation inverter 2. When the switch SW2 is turned off, the feedback resistor Rf2 acts as one of the feedback resistors connected with both the ends of the oscillation inverter 2, so the feedback resistors Rf1 and Rf2 are set for the oscillation inverter 2. On the other hand, when the switch SW2 is turned on, the feedback resistor Rf2 does not act as one of the feedback resistors connected with both the ends of the oscillation inverter 2, so only the feedback resistor Rf1 is set for the oscillation inverter 2. Therefore, a feedback resistance value for the oscillation inverter 2 can be varied by the switch SW2.

Assume that the input terminal of the oscillation circuit is expressed by XIN and the output terminal thereof is expressed by XOUT. The input terminal XIN and the output terminal XOUT are connected with both ends (input and output terminals) of an oscillation resonator 1. The oscillation resonator 1 is a quartz resonator or a ceramic resonator. Hereinafter, the description will be made on the assumption that the oscillation resonator 1 is referred to as the quartz resonator 1.

The input terminal of the quartz resonator 1 which is connected with the input terminal XIN is grounded through an input capacitor cg. The output terminal of the quartz resonator 1 which is connected with the output terminal XOUT is grounded through an output capacitor cd. Each of the input capacitor cg and the output capacitor cd is a capacitor formed by a board or the like.

According to the above-mentioned oscillation circuit using the quartz resonator, the switch for enabling (short-circuiting) the feedback resistor Rf2 connected in series with the feedback resistor Rf1 is provided. Therefore, the feedback resistance value of the single oscillation circuit is switched by the switch to adjust a frequency band of the oscillation circuit, thereby selecting a harmonic component of the quartz resonator. Thus, the oscillation frequency can be switched, so the plurality of oscillation frequencies can be obtained using the single quartz resonator.

### <Principal>

The principal in which the plurality of oscillation frequencies are obtained using the single quartz resonator will be described. Hereinafter, the case where a quartz resonator having a frequency of 32.768 kHz for time measurement is used to obtain 200 kHz which is six times the frequency will be described.

The quartz resonator normally has frequencies which are the multiples of a design frequency. For example, a quarts resonator designed so as to have the frequency of 32.768 kHz includes frequencies of two times, three times, . . . , six times, . . . , and n times (n is natural number), that is, harmonics.

The quartz resonator is normally used such that the oscillation circuit oscillates at only the design frequency of the plurality of frequencies of the quartz resonator to output, for example, only the frequency of 32.768 kHz.

As described above, the quartz resonator having the frequency of 32.768 kHz includes a harmonic of 200 kHz in view of the manufacturing process.

Therefore, in the case the quartz resonator having the frequency of 32.768 kHz is used, when the frequency band of the oscillation circuit side is adjusted, the oscillation can be performed at each of 32.768 kHz and 200 kHz.

Next, the frequency band of the oscillation circuit in the case where the quartz resonator having the frequency of 32.768 kHz oscillates at each of 32.768 kHz and 200 kHz will be described with reference to FIG. 2.

FIG. 2 shows the frequency band of the oscillation circuit. The ordinate represents a negative resistance RL and the abscissa represents a frequency f. The negative resistance RL is a resistance component of the entire oscillation circuit as viewed from the input terminal XIN and the output terminal XOUT.

A wave form indicated by a solid line of FIG. 2 shows a frequency band in the case where the switch of FIG. 1 is turned off and a waveform indicated by a broken line of FIG. 2 shows a frequency band in the case where the switch of FIG. 1 is turned on. Each of the waveforms of FIG. 2 is a waveform obtained by actual measurement or simulation.

As shown in FIG. 2, when the switch is turned off, oscillation is easily performed around 32 kHz. On the other hand, when the switch is turned on, oscillation is easily performed around 200 kHz.

In order to make general characteristics of the frequency bands clear, a change in cutoff frequency fc with respect to the feedback resistance value will be described.

The cutoff frequency fc is particularly a frequency in the case where the negative resistance RL becomes equal to 0 Ω in the oscillation circuit frequency band characteristic graph in which the ordinate represents the negative resistance RL and the abscissa represents the frequency f.

The cutoff frequency fc is calculated by the following Expression 1.

fc∞gm/(Rf·cg·cd) (Expression 1)

where gm indicates inductance a mutual conductance of the oscillation inverter, Rf indicates a feedback resistance, and cg indicates an input capacitance, and cd indicates an output capacitance.

As is apparent from Expression1, the frequency band is adjusted according to the feedback resistance Rf. When the feedback resistance Rf increases, the cutoff frequency fc reduces, so oscillation is performed in the low-frequency band. In contrast to this, when the feedback resistance Rf reduces, the cutoff frequency fc increases, so oscillation is performed in the high-frequency band.

In FIG. 2, assume that the cutoff frequency in the case where the switch is turned off is expressed by fc32 and the cutoff frequency in the case where the switch is turned on is expressed by fc200. It is apparent that the cutoff frequency fc32 in the case where the switch is turned off to increase the feedback resistance Rf is lower than the cutoff frequency fc200 in the case where the switch is turned on to reduce the feedback resistance Rf.

The cutoff frequency fc serves as an index for the output frequency of the oscillation circuit.

As is apparent from the description, when oscillation is to be performed at 32.768 kHz, for example, the switch SW2 is desirably turned off to increase the feedback resistance Rf. When oscillation is to be performed at 200 kHz, the switch SW2 is desirably turned on to reduce the feedback resistance Rf.

When the value of the feedback resistance Rf is varied as described above, the harmonic of the quartz resonator can be selected to easily realize frequency switching.

Each of the feedback resistors Rf1 and Rf2 shown in FIG. 1 has a resistance value determined by performing actual measurement or simulation on the feedback resistance Rf and an oscillation frequency f.

### Second Embodiment

An oscillation circuit oscillating at a harmonic of the quartz resonator which is selected by varying the resistance value of the feedback resistance Rf according to a second embodiment of the present invention will be described with reference to FIG. 3. In FIG. 3, parts corresponding to the respective parts of FIG. 1 are expressed by the same reference symbols and thus the description thereof is omitted.

A feedback resistor Rf3 is a feedback resistor connected in series with the feedback resistors Rf1 and Rf2. An end of the feedback resistor Rf3 is connected with the end (output terminal) of the oscillation inverter 2.

A switch SW3 is a switch for determining whether or not the feedback resistor Rf3 is enabled as one of the series-connected feedback resistors which are connected with the oscillation inverter 2.

In the oscillation circuit, the switch SW2 is turned on and off and the switch SW3 is turned on and off, so the feedback resistance value can be selected from four resistance values. Therefore, the oscillation frequency can be selected from four oscillation frequencies.

When the feedback resistance value is to be easily set, for example, each of the switches is turned off or any one of the switches is turned on.

In this case, the feedback resistance value can be selected from three resistance values, that is, a resistance value of only the feedback resistor Rf1, a combined resistance value of the feedback resistors Rf1 and Rf2, and a combined resistance value of the feedback resistors Rf1 and Rf3. The oscillation frequency is outputted with respect to each of the selected feedback resistance values.

The resistance values of the respective feedback resistors are set according to the harmonics of the quartz resonator.

In FIG. 3, the case where the three feedback resistors are provided is described. However, the present invention is not limited thereto, and thus can be applied to the case where a plurality of feedback resistors are connected in series and a switch is provided for each of the feedback resistors to determine whether or not corresponding one of the feedback resistors is enabled for the oscillation inverter.

With such a structure, it is possible to obtain a plurality of frequencies using the single quartz resonator.

Only the case where the feedback resistors are connected in series is described above. However, the present invention is not limited thereto. For example, a plurality of feedback resistors are connected in series or in parallel and a switch is provided for each of the feedback resistors to determine whether or not corresponding one of the feedback resistors is enabled for the oscillation inverter. In such a case, when each of the switches is turned on or off to vary the feedback resistance value for the oscillation inverter, a plurality of frequencies can be obtained using the single quartz resonator.

### Third Embodiment

An oscillation circuit capable of obtaining a plurality of frequencies using a single quartz resonator according to a third embodiment will be described.

In each of the first embodiment and the second embodiment of the present invention, the structure capable of varying the feedback resistance value is employed. Therefore, the plurality of oscillation frequencies can be obtained using the single quartz resonator.

In contrast to this, in the third embodiment of the present invention, a structure capable of varying the mutual conductance gm of the oscillation inverter, that is, a structure capable of adjusting the current drive capability of the oscillation inverter is employed to obtain a plurality of oscillation frequencies using the single quartz resonator.

This is because, as derived from Expression 1, the cutoff frequency fc is changed by a change in mutual conductance gm of the oscillation inverter. For example, as is apparent from Expression 1, when the mutual conductance gm increases, the cutoff frequency fc becomes larger. On the other hand, when the mutual conductance gm reduces, the cutoff frequency fc becomes smaller.

Therefore, when the mutual conductance gm of the oscillation inverter is made variable, the oscillation frequency can be adjusted. Thus, it is possible to obtain the plurality of frequencies using the single quartz resonator.

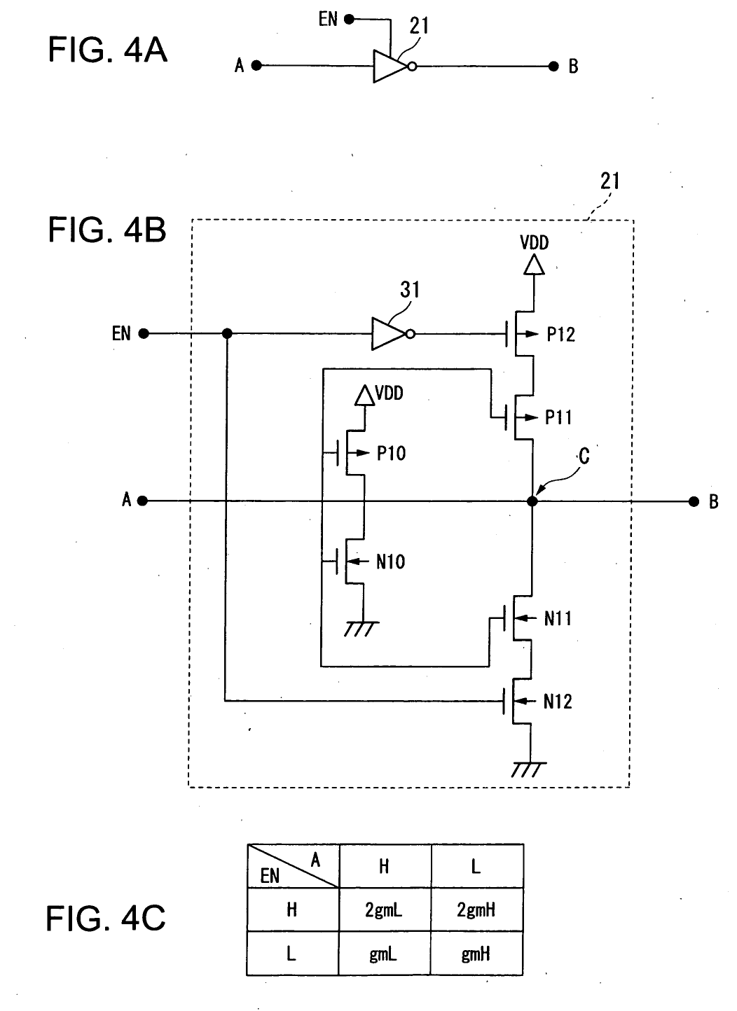

In the third embodiment of the present invention, an oscillation inverter 21 shown in FIG. 4A is used instead of the oscillation inverter 2 of the oscillation circuit shown in each of FIGS. 1 and 3. The oscillation inverter 21 is different from the oscillation inverter 2 of the oscillation circuit shown in each of FIG. 1 and 3 in the point that the mutual conductance gm of the oscillation inverter can be varied.

In each of FIGS. 1 and 3, two connection points connected with the oscillation inverter 2 of the oscillation circuit are referred to a connection point-A and a connection point-B. The oscillation inverter 21 shown in FIG. 4A is connected between the connection point-A and the connection point-B.

A selection signal EN for selecting the mutual conductance gm is inputted from the outside to the oscillation inverter 21 shown in FIG. 4A.

The oscillation inverter 21 shown in FIG. 4A selects one of two set values as a value of the mutual conductance gm of the oscillation inverter 21 based on whether the selection signal EN inputted from the outside is in a high level or in a low level.

In the third embodiment of the present invention, the feedback resistance value is not made variable. For example, the feedback resistor Rf2 and the switch SW2 which are shown in FIG. 1 may be omitted from the oscillation circuit and the oscillation inverter 2 may be replaced by the oscillation inverter 21 shown in FIG. 4A.

A circuit structural example of the oscillation inverter 21 shown in FIG. 4A will be described with reference to FIG. 4B. Hereinafter, the description will be made on the assumption that a power supply potential of a power supply circuit is expressed by VDD and a ground potential thereof is expressed by VSS. The power supply circuit is not shown.

In the following description, a signal inputted from the connection point-A connected with the oscillation inverter 21 is referred to as an input signal-A and a signal outputted from the connection point-B connected therewith is referred to as an output signal-B.

The input signal-A is inputted to a gate of each of a P-channel MOS transistor P10, a P-channel MOS transistor P11, an N-channel MOS transistor N10, and an N-channel MOS transistor N11.

The P-channel MOS transistor P10 has: a drain connected with a drain of the N-channel MOS transistor N10; and a source connected with a terminal of the power supply potential VDD.

The output signal-B is outputted from the connection point between the drain of the P-channel MOS transistor P10 and the drain of the N-channel MOS transistor N10.

The N-channel MOS transistor N10 has a grounded source.

The P-channel MOS transistor P10 and the N-channel MOS transistor N10 act as an inverter to invert the input signal-A and output, to the output terminal-B, a signal obtained by inverting the input signal-A.

Hereinafter, the inverter composed of the P-channel MOS transistor P10 and the N-channel MOS transistor N10 is referred to as a first inverter circuit.

A terminal of the selection signal EN is connected with a gate of an N-channel MOS transistor N12. The terminal of the selection signal EN is connected with a gate of a P-channel MOS transistor P12 through an inverter 31.

The P-channel MOS transistor P12 has a source connected with the power supply circuit. The N-channel MOS transistor N12 has a grounded source.

The P-channel MOS transistor P11 has: a source connected with a drain of the P-channel MOS transistor P12; and a drain connected with the output terminal-B.

The N-channel MOS transistor N11 has: a source connected with a drain of the N-channel MOS transistor N12; and a drain connected with the output terminal-B.

Hereinafter, each of a connection point between the drain of the P-channel MOS transistor P11 and the output terminal-B and a connection point between the drain of the N-channel MOS transistor N11 and the output terminal-B is referred to as a connection point-C.

The operation of the oscillation inverter 21 shown in FIG. 4B will be described.

When the selection signal EN is in a high level, the high-level signal is inputted to the gate of the N-channel MOS transistor N12 to turn on the N-channel MOS transistor N12. Because the source of the N-channel MOS transistor N12 is grounded, the drain thereof is electrically connected the ground point to reduce a potential of the drain to substantially the ground potential VSS.

When the selection signal EN is in a high level, a low-level signal is inputted to the gate of the P-channel MOS transistor P12 to turn on the P-channel MOS transistor P12 because of the intermediation of the inverter 31. Therefore, the drain and the source of the P-channel MOS transistor P12 are electrically connected with each other.

When the input signal-A whose level is high is inputted while the selection signal EN is in a high level, a low-level signal obtained by inverting the input signal-A is outputted from the first inverter circuit.

When the input signal-A whose level is high is inputted, the high-level signal is inputted to the gate of the P-channel MOS transistor P11 to turn off the P-channel MOS transistor P11. Therefore, the source and the drain of the P-channel MOS transistor P11 are electrically disconnected with each other.

When the input signal-A whose level is high is inputted, the high-level signal is inputted to the gate of the N-channel MOS transistor N11 to turn on the N-channel MOS transistor N11. Therefore, the source and the drain of the N-channel MOS transistor N11 are electrically connected with each other.

In this case, because the selection signal EN is in a high level and the drain of the N-channel MOS transistor N12 is grounded, the drain of the N-channel MOS transistor N11 is grounded through the N-channel MOS transistor N12.

Therefore, a potential of the connection point-C is outputted as a low level by two N-channel MOS transistors, that is, the N-channel MOS transistor N10 of the first inverter circuit and the N-channel MOS transistor N11.

When the input signal-A whose level is low is inputted while the selection signal EN is in a high level, a high-level signal obtained by inverting the input signal-A is outputted from the first inverter circuit.

When the input signal-A whose level is low is inputted, the low-level signal is inputted to the gate of the P-channel MOS transistor P11 to turn on the P-channel MOS transistor P11. Therefore, the source and the drain of the P-channel MOS transistor P11 are electrically connected with each other.

When the input signal-A whose level is low is inputted, the low-level signal is inputted to the gate of the N-channel MOS transistor N11 to turn off the N-channel MOS transistor N11. Therefore, the source and the drain of the N-channel MOS transistor N11 are electrically disconnected with each other.

Therefore, a potential of the connection point-C is outputted as a high level by two P-channel MOS transistors, that is, the P-channel MOS transistor P10 of the first inverter circuit and the P-channel MOS transistor P11.

On the other hand, when the selection signal EN is in a low level, a low-level signal is inputted to the gate of the N-channel MOS transistor N12 to turn off the N-channel MOS transistor N12. Therefore, the source of the N-channel MOS transistor N11 is electrically separated from the ground point and thus becomes a floating state.

When the selection signal EN is in a low level, a high-level signal is inputted to the gate of the P-channel MOS transistor P12 through the inverter 31 to turn off the P-channel MOS transistor P12. Therefore, the source of the P-channel MOS transistor P11 is electrically separated from the power supply circuit and thus becomes a floating state.

When the selection signal EN is in a low level, the N-channel MOS transistor N11 and the P-channel MOS transistor P11 do not operate because the N-channel MOS transistor N12 and the P-channel MOS transistor P12 are turned off.

Therefore, when the input signal-A whose level is high is inputted while the selection signal EN is in a low level, a low-level signal is outputted by an N-channel MOS transistor, that is, the N-channel MOS transistor N10 of the first inverter circuit.

When the input signal-A whose level is low is inputted while the selection signal EN is in a low level, a high-level signal is outputted by an P-channel MOS transistor, that is, the P-channel MOS transistor P10 of the first inverter circuit.

The summarized above-mentioned operation of the oscillation inverter 21 will be described with reference to FIG. 4C.

The case where the P-channel MOS transistors P10 and P11 are equal in size to each other and the N-channel MOS transistors N10 and N11 are equal in size to each other will be described.

Assume that a output current or a mutual conductance of a high-level signal which is determined by a P-channel MOS transistor is expressed by gmH and an output current or a mutual conductance of a low-level signal which is determined by an N-channel MOS transistor is expressed by gmL.

In such a case, for example, a mutual conductance of a high-level signal which is determined by two P-channel MOS transistors is 2 gmH. For example, a mutual conductance of a low-level signal which is determined by two N-channel MOS transistors is 2 gmL.

When the input signal-A whose level is high is inputted while the selection signal EN is in a high level, a low-level signal is outputted by two N-channel MOS transistors, that is, the N-channel MOS transistor N10 of the first inverter circuit and the N-channel MOS transistor N11.

Therefore, in this case, the mutual conductance of the oscillation inverter 21 is 2 gmL.

In contrast to this, when the input signal-A whose level is low is inputted while the selection signal EN is in a high level, a high-level signal is outputted by two P-channel MOS transistors, that is, the P-channel MOS transistor P10 of the first inverter circuit and the P-channel MOS transistor P11.

Therefore, in this case, the mutual conductance of the oscillation inverter 21 is 2 gmH.

When the input signal-A whose level is high is inputted while the selection signal EN is in a low level, a low-level signal is outputted by an N-channel MOS transistor, that is, the N-channel MOS transistor N10 of the first inverter circuit.

Therefore, in this case, the mutual conductance of the oscillation inverter 21 is gmL.

By contraries, when the input signal-A whose level is low is inputted while the selection signal EN is in a low level, a high-level signal is outputted by a P-channel MOS transistor, that is, the P-channel MOS transistor P10 of the first inverter circuit.

Therefore, in this case, the mutual conductance of the oscillation inverter 21 is gmH.

The above-mentioned relationships are summarized in a table shown in FIG. 4C. FIG. 4C shows the mutual conductance values of the oscillation inverter 21 in the cases where each of the input signal-A and the selection signal EN is in a high level “H” or in a low level “L”.

Therefore, as shown in FIG. 4C, the mutual conductance gm of the oscillation inverter 21 can be varied based on whether the selection signal EN is in a high level or in a low level.

Thus, the oscillation inverter 21 capable of varying the mutual conductance gm as described above can be used to adjust the oscillation frequency, so a plurality of oscillation frequencies can be obtained using the single quartz resonator.

The mutual conductance values of the oscillation inverter 21, that is, the mutual conductance values of the P-channel MOS transistors P10, P11, and P12 and the mutual conductance values of the N-channel MOS transistors N10, N11, and N12 are set according to the harmonic of the quartz resonator.

In the third embodiment of the present invention, the output current of the oscillation inverter 21 is varied based on whether the selection signal EN is in a high level or in a low level. However, the present invention is not limited thereto. Any structure capable of varying the mutual conductance gm of the oscillation inverter 21 may be used.

For example, a plurality of oscillation inverters whose mutual conductances gm are different from each other and a switch for selecting one of the plurality of oscillation inverters whose mutual conductances gm are different from each other maybe provided, instead of the oscillation inverter 21, to select the mutual conductance gm of any one of the oscillation inverters as the mutual conductance gm of the oscillation inverter 21.

The plurality of oscillation inverters whose mutual conductances gm are different from each other are oscillation inverters which are different in size from each other.

### Fourth Embodiment

An oscillation circuit capable of obtaining a plurality of frequencies using a single quartz resonator according to a fourth embodiment of the present invention will be described.

In the third embodiment of the present invention, the output current of the oscillation inverter 21 is varied based on whether the selection signal EN is in a high level or in a low level. Therefore, the mutual conductance gm of the oscillation inverter 21 is varied to obtain the plurality of frequencies using the single quartz resonator.

In the fourth embodiment, a variable voltage supply is used instead of the fixed voltage supply as described in the third embodiment. Therefore, the mutual conductance gm of the oscillation inverter 21 is made variable to be able to obtain the plurality of frequencies using the single quartz resonator.

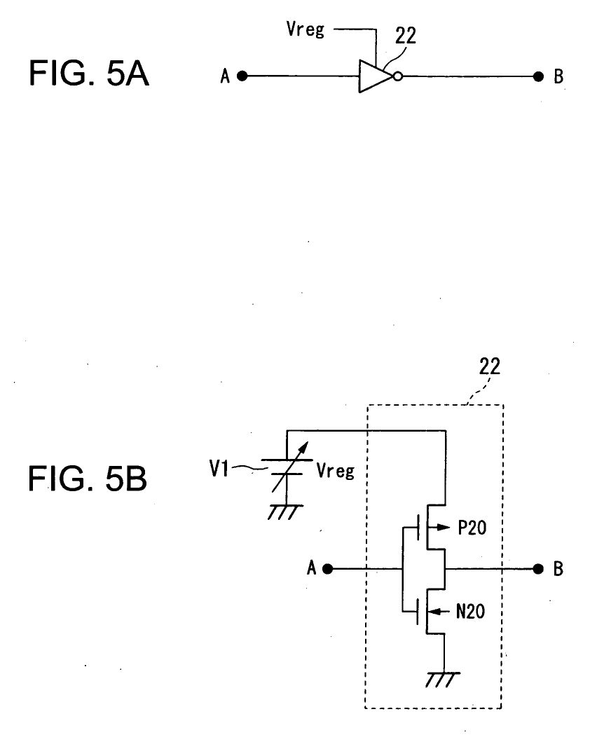

An oscillation inverter 22 in the fourth embodiment will be described with reference to FIG. 5A. The oscillation inverter 22 is an oscillation inverter used instead of the oscillation inverter 2 connected between the connection point-A and the connection point-B as shown in FIG. 1 or 3, as in the case of the oscillation inverter 21 shown in FIG. 4A.

The oscillation inverter 22 adjusts a voltage of the variable voltage supply based on a variable voltage set signal Vreg inputted from the outside, to vary the output signal-B.

A circuit structural example of the oscillation inverter 22 will be described with reference to FIG. 5B.

A variable voltage supply V1 is a voltage supply for adjusting a power supply voltage to be outputted based on the variable voltage set signal Vreg inputted from the outside. One of ends of the variable voltage supply V1 is grounded and the other thereof (output terminal) is used to output the adjusted voltage.

The input signal-A is inputted to a gate of each of a P-channel MOS transistor P20 and an N-channel MOS transistor N20. The P-channel MOS transistor P20 has a source connected with the output terminal of the variable voltage supply V1. The N-channel MOS transistor N20 has a grounded source.

A drain of the P-channel MOS transistor P20 is connected with a drain of the N-channel MOS transistor N20. The output signal-B is outputted from a connection point between the drain of the P-channel MOS transistor P20 and the drain of the N-channel MOS transistor N20.

The P-channel MOS transistor P20 and the N-channel MOS transistor N20 act as an inverter to invert the input signal-A and output, to the output terminal-B, a signal obtained by inverting the input signal-A.

A current outputted to the output terminal-B is varied by adjusting the voltage of the variable voltage supply V1 based on the variable voltage set signal Vreg inputted from the outside.

As described above, according to the oscillation inverter 22, the current outputted to the output terminal-B can be varied by adjusting the output voltage of the variable voltage supply V1 based on the variable voltage set signal Vreg inputted from the outside. Therefore, the value of the mutual conductance gm of the oscillation inverter 22 can be made variable, with the result that it is possible to obtain the plurality of oscillation frequencies using the single quartz resonator.

The value of mutual conductance gm of the oscillation inverter 22 is set according to the harmonic of the quartz resonator.

As is apparent from Expression 1, when the input capacitance cg or the output capacitance cd is made variable, the cutoff frequency fc can be adjusted. Therefore, the input capacitance cg or the output capacitance cd may be made variable to adjust the frequency of the oscillation circuit, thereby obtaining the plurality of oscillation frequencies using the single oscillation resonator.

For example, the following maybe performed. A structure which includes a capacitor cx and a capacitor switch SWX for determining whether or not the capacitor cx is enabled for use with the input capacitor cg is employed. The capacitor switch SWX is on/off controlled. Therefore, one of only the value of the input capacitor cg and a combined value of the input capacitor cg and the capacitor cx is selected as the value of the input capacitance cg to select the frequency of the oscillation circuit, thereby obtaining the plurality of oscillation frequencies using the single oscillation resonator.

As in the case of the input capacitor cg, when a structure including the output capacitor cd whose capacitance value is variable is employed, the plurality of oscillation frequencies can be obtained using the single quartz resonator.

The first to fourth embodiments of the present invention are separately described. However, the present invention is not limited thereto and thus any combination of the first to fourth embodiments may be employed.

When the oscillation circuit in which the plurality of oscillation frequencies are obtained using the single quartz resonator as described above is employed, the period of time required for the function test can be shortened.

For example, when an oscillation circuit capable of generating a normal operation frequency (for example, 32.768 kHz) and a frequency (for example, 200 kHz) higher than the normal operation frequency is provided and the entire circuit operates at the higher frequency (for example, 200 kHz) during the function test, the period of time required for the function test can be shortened.

The quartz oscillation circuit can obtain the plurality of oscillation frequencies using the single quartz resonator. Therefore, when the quartz resonator is operated at a high frequency during the function test, not only the period of time required for the function test can be shortened but also the operation of the entire oscillation circuit can be checked.

The case where the fundamental frequency of 32.768 kHz is used to generate the fundamental frequency and the frequency of 200 kHz which is six times the fundamental frequency is described above. However, the present invention is not limited to this case. When the oscillation circuit is designed so as to oscillate at a harmonic selected from arbitrary harmonics of the quartz resonator, the oscillation circuit can oscillates at the arbitrary harmonic of the quartz resonator.

The case where the oscillation circuit is used for the clock is described above. However, the oscillation circuit according to the present invention is not limited to this case and thus can be applied to any device or apparatus.

The embodiments of the present invention are described in detail above with reference to the attached drawings. Specific structures are not limited to the embodiments and thus include designs made without departing from the scope of the present invention.

### INDUSTRIAL APPLICABILITY

The present invention is suitable for use in a circuit including the oscillation circuit, more particular, a circuit requiring a plurality of frequencies.

What is claimed is:

1. An oscillation circuit, comprising:
an oscillation resonator;
an oscillation inverter which is connected in parallel with the oscillation resonator and includes an output terminal;
a dumping resistor connected with the output terminal of the oscillation inverter; and
a feedback resistor which is connected in parallel with the oscillation inverter and has a variable resistance value.

2. An oscillation circuit according to claim 1, further comprising an oscillation inverter switch for adjusting a current drive capacity of the oscillation inverter.

3. An oscillation circuit, comprising:
an oscillation resonator;
an oscillation inverter which is connected in parallel with the oscillation resonator and includes an output terminal;
a dumping resistor connected with the output terminal of the oscillation inverter; and
a feedback resistor which is connected in parallel with the oscillation inverter; and
an oscillation inverter switch for adjusting a current drive capacity of the oscillation inverter.

4. An oscillation circuit according to claim 3, wherein the feedback resistor has a variable resistance value.

5. An oscillation circuit according to claim 1, wherein the feedback resistor comprises:
a first feedback resistor;
a second feedback resistor; and
a feedback resistor switch connected in parallel with the second feedback resistor.

6. An oscillation circuit according to claim 5, wherein:
the second feedback resistor comprises a plurality of the feedback resistors; and
the feedback resistor switch comprises a plurality of the feedback resistor switches.

7. An oscillation circuit according to claim 2, wherein:
the oscillation inverter comprises a plurality of transistors; and
the number of transistors to be operated is changed based on an input of the oscillation inverter switch.

8. An oscillation circuit according to claim 3, wherein:
the oscillation inverter comprises a plurality of transistors; and
the number of transistors to be operated is changed based on an input of the oscillation inverter switch.

9. An oscillation circuit according to claim 2, wherein the oscillation inverter comprises:
a plurality of oscillation inverter circuits having different current drive capabilities; and
an oscillation inverter circuit selection switch for selecting an oscillation inverter circuit from the plurality of oscillation inverter circuits based on an input of the oscillation inverter switch.

10. An oscillation circuit according to claim 3, wherein the oscillation inverter comprises:
a plurality of oscillation inverter circuits having different current drive capabilities; and
an oscillation inverter circuit selection switch for selecting an oscillation inverter circuit from the plurality of oscillation inverter circuits based on an input of the oscillation inverter switch.

11. An oscillation circuit according to claim 2, wherein the oscillation inverter comprises:
a variable voltage supply for generating a variable voltage based on an input of the oscillation inverter switch; and
an oscillation inverter circuit driven at the variable voltage inputted from the variable voltage supply.

12. An oscillation circuit according to claim 3, wherein the oscillation inverter comprises:
a variable voltage supply for generating a variable voltage based on an input of the oscillation inverter switch; and
an oscillation inverter circuit driven at the variable voltage inputted from the variable voltage supply.
